(19) United States
(12) Patent Application Publication
(10) Pub. No.: US 2015/0263149 A1
(43) Pub. Date: Sep. 17, 2015

(54) SEMICONDUCTOR DEVICE

(71) Applicant: Kabushiki Kaisha Toshiba, Tokyo (JP)

(72) Inventors: Tsuneo Ogura, Kamakura Kanagawa (JP); Shinichiro Misu, Machida Tokyo (JP); Tomoko Matsudai, Shibuya Tokyo (JP); Norio Yasuhara, Kanazawa Ishikawa (JP)

(21) Appl. No.: 14/485,028

(22) Filed: Sep. 12, 2014

(30) Foreign Application Priority Data
Mar. 17, 2014 (JP) 2014-053320

(51) Int. Cl. H01L 29/739

(52) U.S. Cl. CPC H01L 29/7395

(57) ABSTRACT

According to one embodiment, a semiconductor device includes a first electrode, a second electrode, a first semiconductor region, a second semiconductor region, an insulating region, and a third semiconductor region. The first semiconductor region is of a first conductivity type. The first semiconductor region is provided between the first electrode and the second electrode, and contacts the first electrode. The second semiconductor region is of a second conductivity type. The second conductor region is provided between the first semiconductor region and the second electrode. The insulating region extends from the second electrode to a side of the first semiconductor region. The third semiconductor region is of the first conductivity type. The third semiconductor region is provided in at least a portion of a region between the second semiconductor region and the insulating region, and contacts the first semiconductor region.

### CROSS-REFERENCE TO RELATED APPLICATIONS

This application is based upon and claims the benefit of priority from Japanese Patent Application No. 2014-053320, filed on Mar. 17, 2014; the entire contents of which are incorporated herein by reference.

### FIELD

Embodiments described herein relate generally to a semiconductor device.

### BACKGROUND

In recent years, insulated gate bipolar transistors (IGBTs), diodes, and the like are used as semiconductor devices used in power conversion devices such as inverters. The diodes are generally connected in an antiparallel manner to the IGBTs and are used as refluxing diodes. Because of this, the diodes are sometimes referred to as free wheeling diodes (FWDs).

Characteristic improvement of the FWDs is crucial on a par with characteristic improvement of the IGBTs in characteristic improvement of the power conversion devices such as the inverters. Crucial characteristics of the FWDs include an ON voltage (that is, a voltage drop in a conduction state), a recovery time (that is, an extinction time of a recovery current upon recovery), a safe operation region upon recovery (that is, a region not destroyed even if a voltage is applied in a state where the recovery current is flowing), and the like. Moreover, a smaller current and voltage oscillation upon recovery is more desirable. Among these, widening the safe operation region upon recovery while shortening the recovery time is crucial.

### BRIEF DESCRIPTION OF THE DRAWINGS

FIG. 1A is a schematic cross-sectional view illustrating a semiconductor device according to a first embodiment, and FIG. 1B is a schematic plan view illustrating the semiconductor device according to the first embodiment;

FIG. 2A and FIG. 2B are schematic cross-sectional views illustrating an operation in an ON state of the semiconductor device according to the first embodiment, and FIG. 2C is a diagram showing a carrier concentration distribution in the ON state of the semiconductor device according to the first embodiment and according to a reference example;

FIG. 3A and FIG. 3B are schematic cross-sectional views illustrating an operation in a recovery state of the semiconductor device according to the first embodiment;

FIG. 4A to FIG. 4C are schematic cross-sectional views illustrating an example of a manufacturing process of the semiconductor device according to the first embodiment;

FIG. 5A and FIG. 5B are schematic cross-sectional views illustrating a manufacturing process of the semiconductor device according to the first embodiment;

FIG. 6 is a schematic cross-sectional view illustrating a semiconductor device according to a first variation of the first embodiment;

FIG. 7A is a schematic cross-sectional view illustrating a semiconductor device according to a second variation of the first embodiment, and FIG. 7B is a schematic cross-sectional view illustrating an operation in a recovery state thereof;

FIG. 8A is a schematic cross-sectional view illustrating a semiconductor device according to a third variation of the first embodiment, and FIG. 8B is a schematic plan view illustrating the semiconductor device according to the third variation of the first embodiment;

FIG. 9A and FIG. 9B are schematic cross-sectional views illustrating a semiconductor device according to a second embodiment;

FIG. 10A is an example of a circuit diagram of the semiconductor device according to the second embodiment, and FIG. 10B is a time chart illustrating an operation of the semiconductor device according to the second embodiment;

FIG. 11 is a schematic cross-sectional view illustrating a semiconductor device according to a variation of the second embodiment;

FIG. 12A is a schematic cross-sectional view illustrating a semiconductor device according to a third embodiment, and FIG. 12B is a schematic cross-sectional view illustrating an operation thereof; and

FIG. 13 is a schematic cross-sectional view illustrating a semiconductor device according to a fourth embodiment.

### DETAILED DESCRIPTION

According to one embodiment, a semiconductor device includes a first electrode, a second electrode, a first semiconductor region, a second semiconductor region, an insulating region, and a third semiconductor region. The first semiconductor region is of a first conductivity type. The first semiconductor region is provided between the first electrode and the second electrode, and contacts the first electrode. The second semiconductor region is of a second conductivity type. The second conductor region is provided between the first semiconductor region and the second electrode. The insulating region extends from the second electrode to a side of the first semiconductor region. The third semiconductor region is of the first conductivity type. The third semiconductor region is provided in at least a portion of a region between the second semiconductor region and the insulating region, and contacts the first semiconductor region.

Various embodiments will be described hereinafter with reference to the accompanying drawings. In the following description, the same reference numeral is applied to the same member, and for members that have been described once, the description is omitted as appropriate.

### First Embodiment

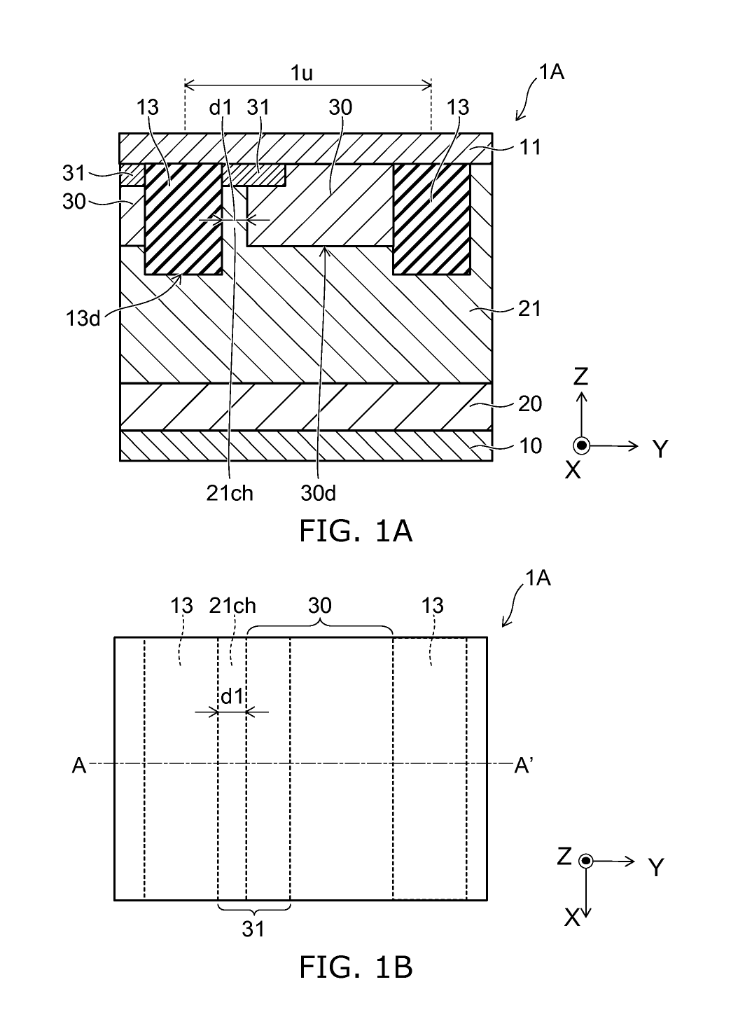

FIG. 1A is a schematic cross-sectional view illustrating a semiconductor device according to a first embodiment, and FIG. 1B is a schematic plan view illustrating the semiconductor device according to the first embodiment.

The A-A′ cross section of FIG. 1B is illustrated in FIG. 1A. The range 1u illustrated in FIG. 1A is a range of a smallest unit of a semiconductor device 1A. The semiconductor device 1A uses the smallest unit to exhibit an action effect that will be described below.

The semiconductor device 1A is a type of a pin (p-intrinsic-n) diode. The semiconductor device 1A is used, for example, as a free wheeling diode such as an inverter circuit.

The semiconductor device 1A is provided with a cathode electrode 10 (first electrode) and an anode electrode 11 (second electrode). An n⁺-type semiconductor region 20 is provided between the cathode electrode 10 and the anode electrode 11. The semiconductor region 20 contacts the cathode electrode 10. The semiconductor region 20 is in ohmic contact with the cathode electrode 10.

An n-type semiconductor region 21 is provided between the semiconductor region 20 and the anode electrode 11. The semiconductor region 20 and the semiconductor region 21 are combined to define a first semiconductor region. An impurity concentration of the semiconductor region 21 is less than an impurity concentration of the semiconductor region 20.

A concentration of impurity elements included in the semiconductor region 21 may be set to be less than a concentration of impurity elements included in the semiconductor region 20 on a face where the semiconductor region 20 contacts the cathode electrode 10. Moreover, an n-type buffer layer (not illustrated) may be provided between the semiconductor region 21 and the semiconductor region 20. An impurity concentration of the buffer layer is set, for example, to be between the impurity concentration included in the semiconductor region 21 and the impurity concentration included in the semiconductor region 20.

A p-type semiconductor region 30 (second semiconductor region) is provided between the semiconductor region 21 and the anode electrode 11. The semiconductor region 30 is in Schottky contact or in ohmic contact with the anode electrode 11. A layer thickness of the semiconductor region 30 is, for example, from 0.5 μm (micrometers) to 10 μm.

An insulating region 13 is provided so as to be separated from the semiconductor region 30 with a gap dl in at least a portion of a region in a Y-direction (third direction). That is, the insulating region 13 and the semiconductor region 30 are separated in at least a portion of a region in the Y-direction. The insulating region 13 extends from the anode electrode 11 to a side of the semiconductor region 21. The semiconductor region 21 is sandwiched between the insulating region 13 and the semiconductor region 30. The insulating region 13 contacts the anode electrode 11. A distance between the insulating region 13 and the cathode electrode 10 is shorter than a distance between the semiconductor region 30 and the cathode electrode 10. That is, a lower portion 13d of the insulating region 13 is at a position lower than a lower portion 30d of the semiconductor region 30. Moreover, a plurality of insulating regions 13 is provided, and an insulating region 13 adjacent to the insulating region 13 described above passes through the semiconductor region 30 from the anode electrode 11 and reaches the semiconductor region 21.

A p⁺-type semiconductor region 31 (fourth semiconductor region) is provided between the anode electrode 11 and the semiconductor region 21 and between the anode electrode 11 and the semiconductor region 30. The semiconductor region 31 contacts the anode electrode 11 and the insulating region 13. An impurity concentration (or a maximum value or an average value of an impurity concentration profile in a Z-direction) of the semiconductor region 31 is greater than an impurity concentration (or the maximum value or the average value of the impurity concentration profile in the Z-direction) of the semiconductor region 30.

The semiconductor region 31 is in ohmic contact with the anode electrode 11. For example, a concentration of impurity elements included in the semiconductor region 31 on a face where the semiconductor region 31 contacts the anode electrode 11 is greater than a concentration of impurity elements included in the semiconductor region 30 on a face where the semiconductor region 30 contacts the anode electrode 11. A layer thickness of the semiconductor region 31 is, for example, from 0.1 μm to 5 μm.

As illustrated in FIG. 1B, the insulating region 13, the semiconductor region 30, and the semiconductor region 31 each extend in an X-direction (second direction) that intersects the Z-direction (first direction) heading toward the cathode electrode 10 from the anode electrode 11.

A main component of each of the semiconductor regions 20, 21, 30, and 31 is, for example, silicon (Si). Phosphorus (P), arsenic (As), or the like, for example, is applied as an impurity element of a conductivity type (first conductivity type) such as an n⁺-type or an n-type. Boron (B) or the like is applied, for example, as an impurity element of a conductivity type (second conductivity type) such as a p⁺-type or a p-type. Moreover, in addition to silicon (Si), the main component of each of the semiconductor regions 20, 21, 30, and 31 may be silicon carbide (SiC), gallium nitride (GaN), or the like.

Moreover, a maximum value of the impurity concentration of the semiconductor region 20 is greater than 3×10¹⁷ cm⁻³ and is, for example, 1×10¹⁸ cm⁻³ or greater. The impurity concentration of the semiconductor region 20 may be set to increase toward the cathode electrode 10. The impurity concentration of the semiconductor region 21 is, for example, 1×10¹⁵ cm⁻³ or less and can be set to any impurity concentration by a breakdown voltage design of a device. The maximum value of the impurity concentration of the semiconductor region 30 is, for example, 1×10¹⁸ cm⁻³ or less. The maximum value of the impurity concentration of the semiconductor region 31 is greater than 3×10¹⁷ cm⁻³ and is, for example, 1×10¹⁹ cm⁻³ or greater. These impurity concentrations of the p-type semiconductor regions may be set to increase toward the anode electrode 11.

Furthermore, the “impurity concentration” described above refers to an effective concentration of impurity elements contributing to conductivity of a semiconductor material. For example, if the semiconductor material contains impurity elements that act as donors and impurity elements that act as acceptors, a concentration where an offset amount of the donors and acceptors is removed from among the activated impurity elements is defined as the impurity concentration.

Furthermore, in the embodiment, unless otherwise specified, the concentration of the n-type impurity elements is represented as decreasing in order of the n⁺-type and then the n-type. Moreover, the concentration of the p-type impurity elements is represented as decreasing in order of the p⁺-type and then the p-type. Moreover, in the semiconductor device 1A, a similar effect can be obtained even if the conductivity types of p and n are interchanged.

Furthermore, in the embodiment, unless otherwise specified, the impurity concentration of the n⁺-type semiconductor region being greater than the impurity concentration of the n-type semiconductor region also includes a situation where the impurity concentration of the n⁺-type semiconductor region on a face of the n⁺-type semiconductor region that contacts the cathode electrode 10 is greater than the impurity concentration of the n-type semiconductor region. Moreover, in the embodiment, the impurity concentration of the p⁺-type semiconductor region being greater than the impurity concentration of the p-type semiconductor region also includes a situation where the impurity concentration of the p⁺-type semiconductor region on a face of the p⁺-type semiconductor region that contacts the anode electrode 11 is greater than the impurity concentration of the p-type semiconductor region on a face of the p-type semiconductor region that contacts the anode electrode 11.

A material of the cathode electrode 10 and a material of the anode electrode 11 are, for example, a metal that includes at least one selected from the group consisting of aluminum (Al), titanium (Ti), nickel (Ni), tungsten (W), gold (Au), and the like.

An operation of the semiconductor device 1A will be described.

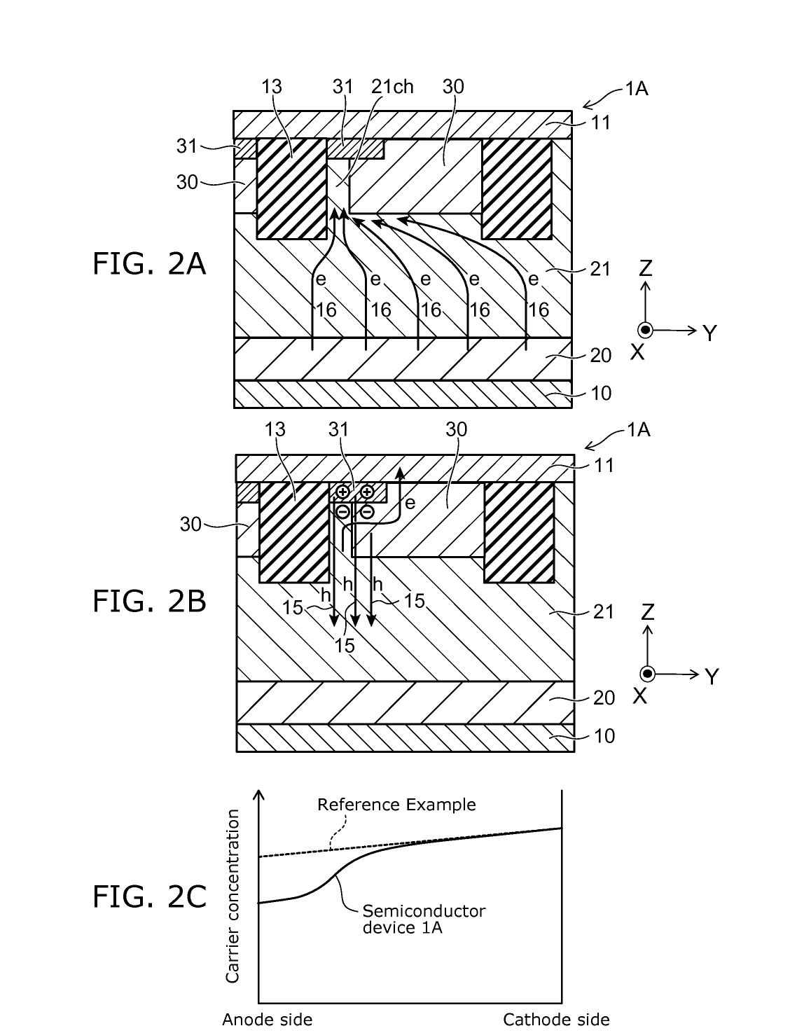

FIG. 2A and FIG. 2B are schematic cross-sectional views illustrating an operation in an ON state of the semiconductor device according to the first embodiment, and FIG. 2C is a diagram showing a carrier concentration distribution in the ON state of the semiconductor device according to the first embodiment and according to a reference example.

First, an electron current that flows from a cathode side to an anode side will be described using FIG. 2A.

In the ON state, a forward bias voltage is applied between a cathode and an anode. That is, a voltage is applied between the cathode and the anode so that a potential of the anode electrode 11 is greater than a potential of the cathode electrode 10. For example, the anode electrode 11 is a positive electrode and the cathode electrode 10 is a negative electrode.

Here, the semiconductor region 20 is in ohmic contact with the cathode electrode 10. Therefore, most electrons (e) arrive directly below the semiconductor region 30 from the semiconductor region 20 via the semiconductor region 21.

The semiconductor device 1A has the semiconductor region 21 provided in at least a portion of a region between the semiconductor region 30 and the insulating region 13. In the embodiment, the semiconductor region 21 sandwiched between the semiconductor region 30 and the insulating region 13 is referred to as a channel region 21ch (third semiconductor region). The channel region 21ch contacts the semiconductor region 21. The channel region 21ch and the semiconductor region 21 may be collectively defined as the semiconductor region 21.

The channel region 21ch is the n-type. Therefore, as illustrated in FIG. 2A, the electrons flow to the anode electrode 11 via the channel region 21ch, which has a low potential, rather than crossing over an energy barrier between the semiconductor region 21 and the semiconductor region 30.

Note that the semiconductor region 30 is in resistive contact or in Schottky contact with the anode electrode 11. That is, this contact is resistive contact or Schottky contact between a p-type semiconductor and a metal. Here, in case that a junction between the semiconductor region 30 and the anode electrode 11 is Schottky contact, while the junction between the semiconductor region 30 and the anode electrode 11 is an energy barrier for holes (h), this region is not an energy barrier for the electrons (e). By this, the electrons are discharged to the anode electrode 11 via the semiconductor region 30.

In this manner, the electrons (e) flow into the anode electrode 11 via the semiconductor region 20, the semiconductor region 21, the channel region 21ch, and the semiconductor region 30. By this, an electron current 16 is formed between the cathode and the anode.

Next, a hole current flowing from the anode side to the cathode side during forward bias application is illustrated in FIG. 2B.

As described above, the junction between the semiconductor region 30 and the anode electrode 11 is not an energy barrier for the electrons (e). However, a junction between the semiconductor region 31, which is a p-type high-concentration layer, and the n-type semiconductor region 21 is an energy barrier for the electrons (e). Therefore, the electrons that arrive directly below the semiconductor region 31 are less likely to flow into the semiconductor region 31. After this, the electrons (e) move in a horizontal direction below the semiconductor region 31, that is, a direction approximately parallel to the Y-direction.

By this horizontal movement of the electrons (e), a voltage drop occurs below the semiconductor region 31. By this, the semiconductor region 31 contacting the anode electrode 11 becomes a positive electrode, and the semiconductor region 21 and the semiconductor region 30 positioned below the semiconductor region 31 are biased so as to become a negative electrode relative to the semiconductor region 31.

By this bias, an energy barrier against the holes between the semiconductor region 21 and semiconductor region 30 and between the semiconductor region 21 and the semiconductor region 31 decreases below the semiconductor region 31. By this, the holes (h) are injected in the semiconductor region 21 and the semiconductor region 30 from the semiconductor region 31. A hole current 15 is formed by these injected holes (h).

The hole current 15 increases as a width of the semiconductor region 31 in the Y-direction or in the X-direction, or a contact surface area between the semiconductor region 31 and the anode electrode 11, increases. In other words, an injection amount of the holes from the anode side is adjusted by this width or this contact surface area.

In the semiconductor device 1A, the electrons flow to the anode electrode 11 via the channel region 21ch. That is, the electrons are less likely to flow to the anode electrode 11 from the semiconductor region 21 directly below the semiconductor region 30 via the semiconductor region 30.

If the electrons are injected in the semiconductor region 30 from the semiconductor region 21, hole injection induced by this electron injection occurs from the semiconductor region 30 to the semiconductor region 21. In the semiconductor device 1A, this hole injection is reliably suppressed by flowing the electrons to the anode electrode 11 via the channel region 21ch.

Carrier concentration distribution is shown in FIG. 2C. The reference example is, for example, a device where the channel region 21ch is removed from the semiconductor device 1. A carrier concentration on the anode side in the first embodiment is lower than that of the reference example. That is, FIG. 2C shows how, in the first embodiment, hole injection from the semiconductor region 30 decreases because the electrons injected from the cathode side flow to the anode electrode 11 via the n-type channel region 21ch.

In this manner, in the ON state, the holes flow from the anode side to the cathode side and the electrons flow from the cathode side to the anode side. On the anode side, in contrast to the holes being injected from the semiconductor region 31, the injection amount of the holes from the semiconductor region 30 is small, and the semiconductor region 30 mainly contributes in discharging the electrons. By this, in the semiconductor device 1A, a recovery speed thereof speeds up.

Next, a recovery operation of the semiconductor device 1A will be described.

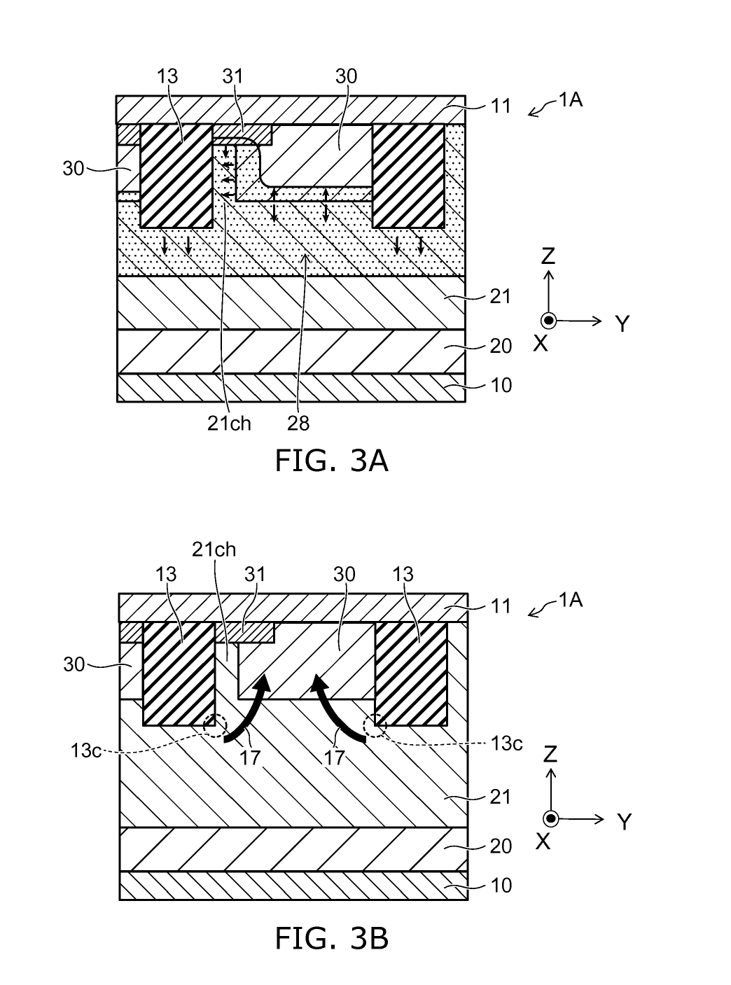

FIG. 3A and FIG. 3B are schematic cross-sectional views illustrating an operation in a recovery state of the semiconductor device according to the first embodiment.

Illustrated in FIG. 3A is a state upon recovery where a reverse bias is applied after a state where a forward bias is applied between the anode and the cathode. Here, a voltage is applied between the cathode and the anode so that the anode electrode 11 is a negative electrode and the cathode electrode 10 is a positive electrode.

When the reverse bias is applied between the anode and the cathode after the state where the forward bias is applied between the anode and the cathode, the holes (h) present in the semiconductor region 21 move to a side of the anode electrode 11. Moreover, the electrons (e) present in the semiconductor region 21 move to a side of the cathode electrode 10.

Here, the electrons (e) flow into the cathode electrode 10 via the semiconductor region 20. Meanwhile, the holes (h) flow into the anode electrode 11 via the semiconductor region 31.

Upon recovery, in a state where the electrons are flowing to the cathode electrode 10 and the holes are flowing to the anode electrode 11, a depletion layer 28 spreads in the semiconductor region 21, the semiconductor region 30, and the semiconductor region 31 from a junction of the semiconductor region 30 and the semiconductor region 21 or from a junction of the semiconductor region 31 and the semiconductor region 21, as the PN junctions being starting points. By this, conduction between the anode electrode 11 and the cathode electrode 10 in the semiconductor device 1A is gradually cut off.

Here, in the channel region 21ch, whose width in the Y-direction is narrow, the depletion layer 28 spreads from the junction of the semiconductor region 30 and the semiconductor region 21 and from the junction of the semiconductor region 31 and the semiconductor region 21 as the starting points. Because of this, the channel region 21ch is completely depleted. Therefore, in the semiconductor device 1A, a backward current (leakage current) is reliably suppressed when the reverse bias is applied. Note that to completely deplete the channel region 21ch, it is noted that the width of the channel region 21ch is sufficiently narrow, for example, 1 μm or less.

However, in a pin diode, there is generally a situation where electric field concentration occurs at any location of a PN junction in a semiconductor chip upon recovery to induce an avalanche. In the first embodiment, because the holes (h) flow into the anode electrode 11 via the semiconductor region 31, an adverse effect induced by this avalanche is suppressed and a safe operation region upon recovery is enlarged.

Illustrated in FIG. 3B is an operation in the recovery state of the semiconductor device 1A.

For example, the insulating region 13 has a corner portion 13c positioned inside the semiconductor region 21. An electric field is easily focused on this corner portion 13c upon recovery. By this, the avalanche easily occurs near the corner portion 13c. A flow of holes (h) generated by the avalanche is defined as an avalanche current 17. Then, the avalanche current 17 is discharged to the anode electrode 11 via the semiconductor region 31. Because of this, it is noted that the gap 1u between the insulating regions 13 is sufficiently narrow, and it is favorable for the gap 1u to be, preferably, 10 μm or less.

Furthermore, a plurality of corner portions 13c (insulating regions 13) is provided in the semiconductor device 1A. In the semiconductor device 1A, because the avalanche occurs easily at each of the plurality of corner portions 13c, a location where the avalanche occurs is dispersed. Therefore, the avalanche current is also dispersed near each of the plurality of corner portions 13c. Then, the avalanche current is discharged to the anode electrode 11 via each of the plurality of semiconductor regions 31. By this, a breakdown tolerance of the semiconductor device 1A upon recovery increases.

Note that this structure has the semiconductor region 31 that is the p-type high-concentration layer and is not provided with a semiconductor region that is an n-type high-concentration layer in a position similar to that of the semiconductor region 31. Moreover, if the PN junction is not present, the electric field cannot be applied in an OFF state to the semiconductor region that is the n-type high-concentration layer and the channel region 21ch configured by the n-type semiconductor layer. An electric field being able to be applied in the OFF state and a breakdown voltage being able to be had even in a switching state or a static OFF state due to the embodiment having the semiconductor region 31 that is the p-type high-concentration layer are significant features and are disclosed for the first time in the embodiment.

As described above, with the semiconductor device 1A according to the first embodiment, both speeding up the recovery speed and increasing the breakdown tolerance upon recovery, that is, enlarging the safe operation area (SOA), can be achieved.

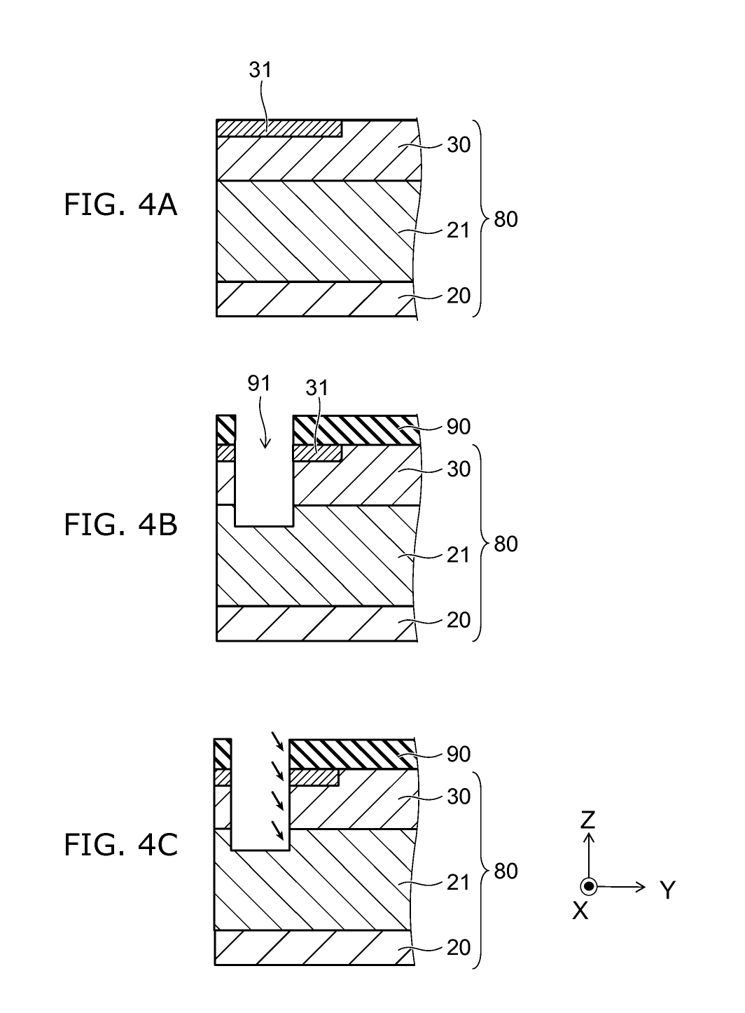

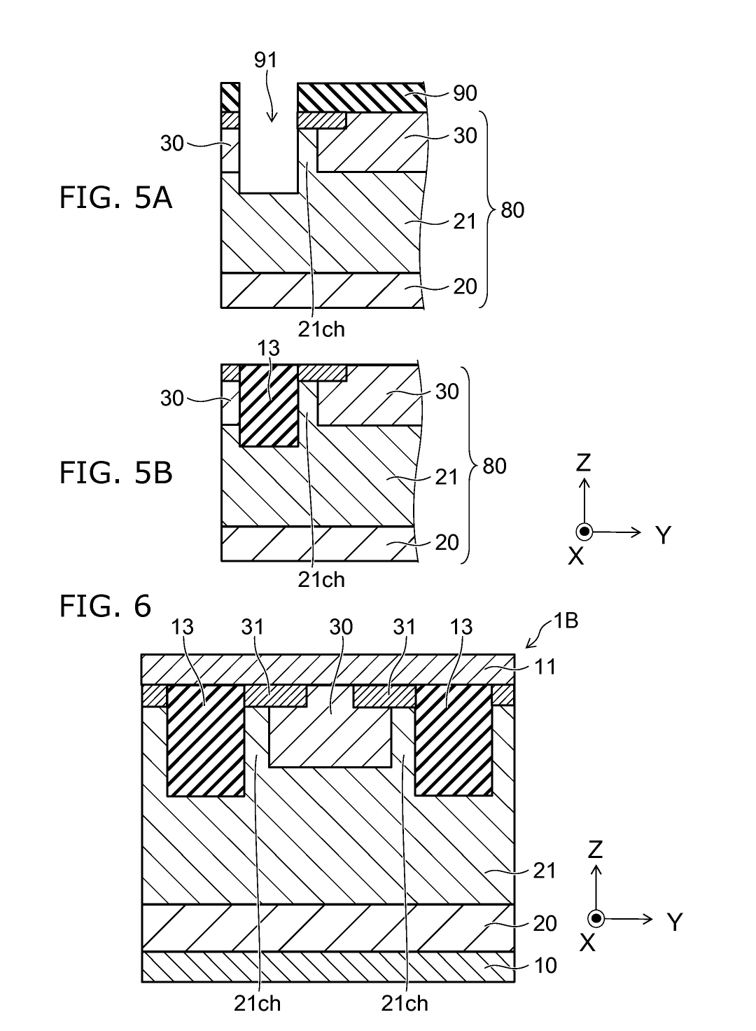

FIG. 4A to FIG. 5B are schematic cross-sectional views illustrating an example of a manufacturing process of the semiconductor device according to the first embodiment.

First, as illustrated in FIG. 4A, a stacked body 80 having the semiconductor region 20, the semiconductor region 21, and the semiconductor region 30 is prepared. Here, the semiconductor region 31 is selectively formed on the semiconductor region 30.

Next, as illustrated in FIG. 4B, a mask pattern 90 is formed on the stacked body 80, and an etching process is applied on the stacked body 80 opened through the mask pattern 90. By this, a trench 91 that reaches from a surface of the stacked body 80 to the semiconductor region 21 is formed.

Next, as illustrated in FIG. 4C, n-type impurity elements (for example, phosphorus, arsenic, or the like) are implanted in the semiconductor region 30 exposed in the trench 91. Here, an oblique ion implantation method that implants the n-type impurity elements in a direction of the arrow in FIG. 4B is used.

Next, an annealing treatment is applied on the stacked body 80. By this, as illustrated in FIG. 5A, the channel region 21ch is formed along a first inner wall of the trench 91. After this, the mask pattern 90 is removed.

Next, as illustrated in FIG. 5B, the insulating region 13 is formed in the trench 91. After this, as illustrated in FIG. 1A, the anode electrode 11 and the cathode electrode 10 are formed.

### First Variation of the First Embodiment

FIG. 6 is a schematic cross-sectional view illustrating a semiconductor device according to a first variation of the first embodiment.

The channel region 21 is not limited to a structure of being provided on one side of the semiconductor region 30 in the Y-direction. For example, as in a semiconductor device 1B illustrated in FIG. 6, the channel region 21 may be provided on both sides of the semiconductor region 30. Such a structure enables achievement both further speeding up the recovery speed and increasing the breakdown tolerance upon recovery, that is, enlarging the safe operation area (SOA). This is because injected carriers can be further reduced and speeding up can be achieved due to an effective area of the channel region 21ch increasing and because the avalanche current is easier to discharge due to an effective area of the semiconductor region 31 increasing.

### Second Variation of the First Embodiment

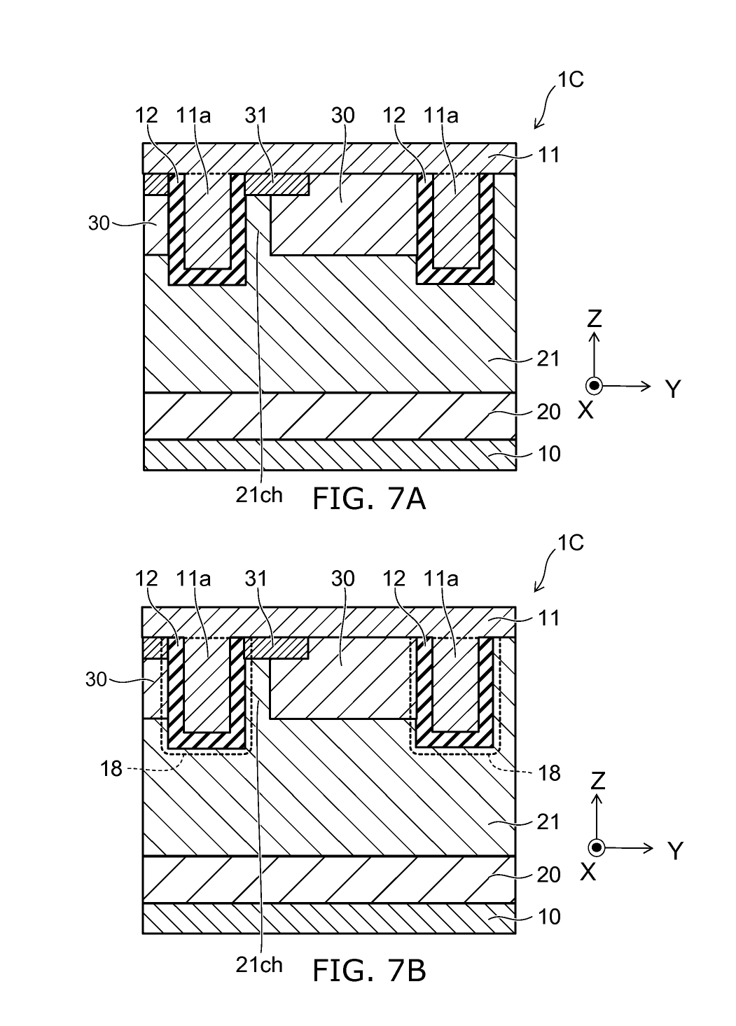

FIG. 7A is a schematic cross-sectional view illustrating a semiconductor device according to a second variation of the first embodiment, and FIG. 7B is a schematic cross-sectional view illustrating an operation in a recovery state thereof.

In a semiconductor device 1C illustrated in FIG. 7A, a portion of the insulating region 13 described above is configured as a connecting region 11a and an insulating region 12. The connecting region 11a contacts the anode electrode 11a. The connecting region 11a is provided between the anode electrode 11 and the insulating region 12. The connecting region 11a includes, for example, polysilicon. A material of the connecting region 11a is polysilicon but is not limited to polysilicon and may be the same material as that of the anode electrode 11.

The connecting region 11a extends toward the cathode electrode 10 from the anode electrode 11. The connecting region 11a and the insulating region 12 extend, for example, in the X-direction. The connecting region 11a and the insulating region 12 are arranged, for example, in the Y-direction.

Furthermore, because an identical negative potential is applied to the connecting region 11a upon recovery as the anode electrode 11, a layer 18 whose hole concentration is increased is induced along the insulating region 12 (FIG. 7B). This layer 18 is a layer with low resistance against the holes (h). That is, forming the layer 18 of low resistance further increases an efficiency of the holes (h) being discharged to the anode electrode 11. Moreover, by this, the breakdown tolerance upon recovery can be increased. That is, a characteristic is that a width of the channel region 21ch becomes narrow due to the layer 18 whose hole concentration is increased and a breakdown voltage during voltage application thereby becomes more sufficient.

### Third Variation of the First Embodiment

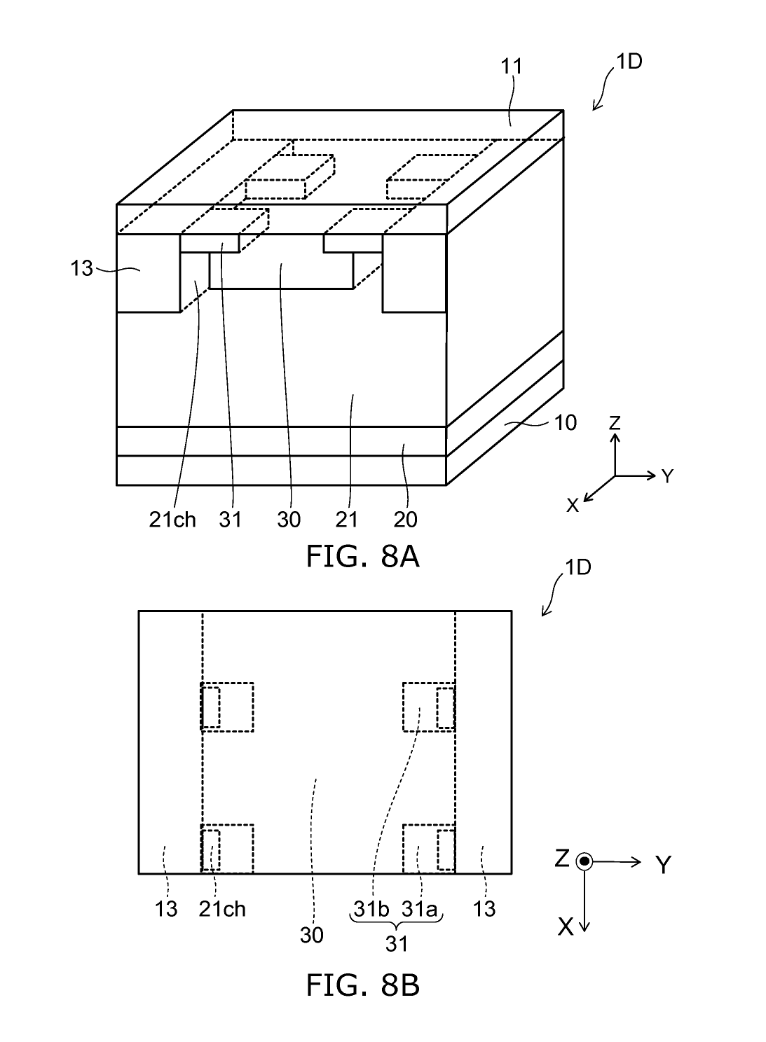

FIG. 8A is a schematic cross-sectional view illustrating a semiconductor device according to a third variation of the first embodiment, and FIG. 8B is a schematic plan view illustrating the semiconductor device according to the third variation of the first embodiment.

In a semiconductor device 1D, the semiconductor region 31 is divided into a plurality of regions 31a. Each of the plurality of regions 31a is lined up in the X-direction. That is, the semiconductor region 31 is disposed by being thinned out in the X-direction.

In the semiconductor device 1D, there is, in the X-direction, a region where the semiconductor region 31 is provided and a region where the semiconductor region 31 is not provided. By this, the contact surface area between the semiconductor region 31 and the anode electrode 11 further decreases. As a result, in the semiconductor device 1D, the injection amount of the holes from the anode side is further suppressed, and the recovery speed thereof is sped up further.

### Second Embodiment

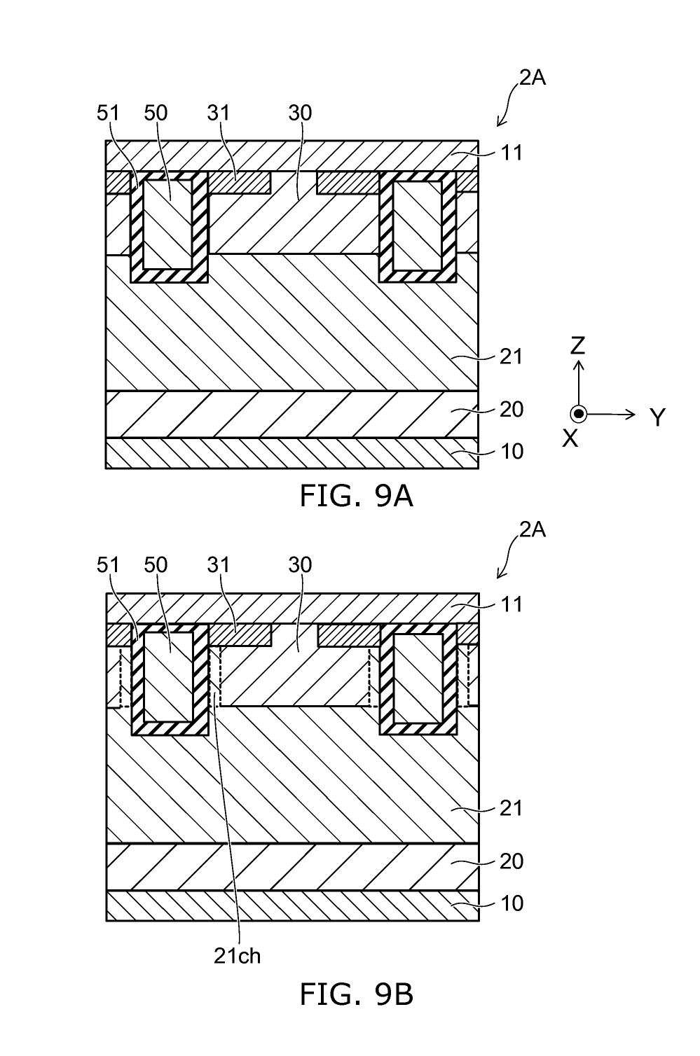

FIG. 9A and FIG. 9B are schematic cross-sectional views illustrating a semiconductor device according to a second embodiment.

A semiconductor device 2A illustrated in FIG. 9A is provided with the cathode electrode 10 and the anode electrode 11, similar to the semiconductor device 1A. Moreover, the semiconductor device 2A is provided with the semiconductor region 20, the semiconductor region 21, the semiconductor region 30, and the semiconductor region 31. The semiconductor region 31 contacts the anode electrode 11 and an insulating film 51.

However, in the semiconductor device 2A, a portion of the insulating region 13 described above is configured as an electrode 50 and the insulating film 51 (insulating region). The electrode 50 contacts the semiconductor region 21, the semiconductor region 30, and the semiconductor region 31 via the insulating film 51. The electrode 50 is electrically insulated from the anode electrode 11. The electrode 50 is provided in the insulating film 51. In the semiconductor device 2A, the channel region 21ch can be formed by applying a positive bias relative to the anode electrode 11 on the electrode 50. Because of this, one characteristic of the embodiment is being able to be easily manufactured in terms of process.

For example, a state where a positive potential (for example, +15 V) is applied on the electrode 50 is illustrated in FIG. 9B. In this situation, an n-type inversion layer is formed along the insulating film 51 on the semiconductor region 30, and the channel region 21ch is formed substantially between the semiconductor region 30 and the insulating film 51. That is, the semiconductor device 2A is substantially of the same configuration as the semiconductor device 1A in the state where the positive potential is applied on the electrode 50.

Therefore, in the semiconductor device 2A as well, both speeding up the recovery speed and increasing the breakdown tolerance upon recovery, that is, enlarging the safe operation region, can be achieved. Note that in the semiconductor region 2A, the semiconductor region 31 may be divided into the plurality of regions 31a, and each of the plurality of regions 31a may be arranged in the X-direction.

Note that a potential of the electrode 50 may be controlled, via, for example, an electrode terminal, by a gate driver of an IGBT included with the semiconductor device 2A in the semiconductor chip or may be controlled by a driver for an FWD.

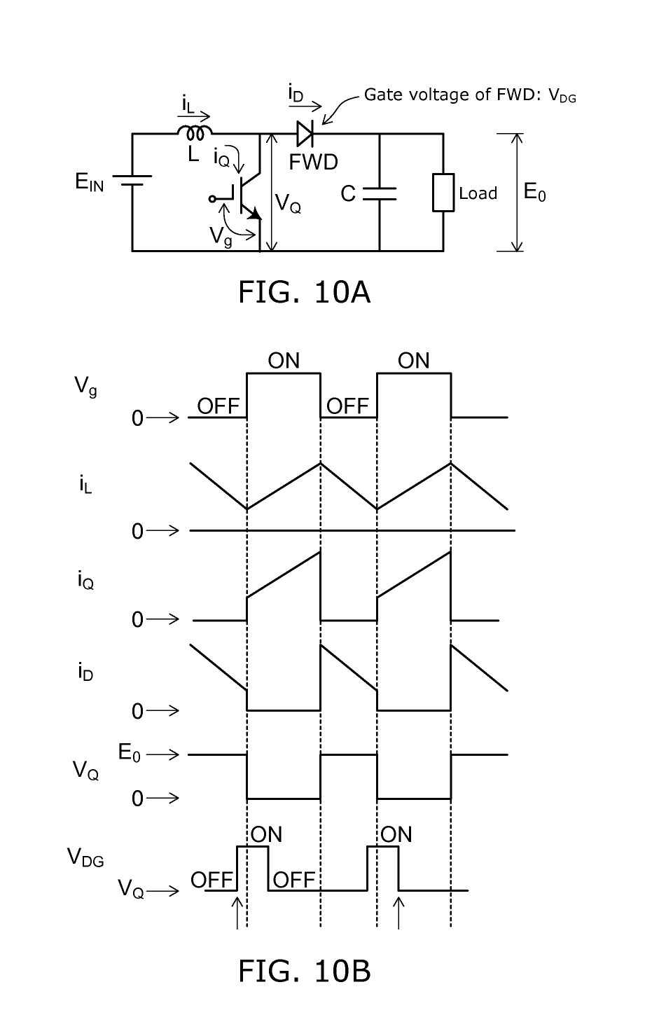

FIG. 10A is an example of a circuit diagram of the semiconductor device according to the second embodiment, and FIG. 10B is a time chart illustrating an operation of the semiconductor device according to the second embodiment.

A booster circuit is illustrated in FIG. 10A as an example. The semiconductor device 2A is used as an FWD. FIG. 10A is a simple booster circuit, but by connecting a separate IGBT in parallel with the FWD and connecting a separate FWD in parallel with the IGBT, a bidirectional converter can be configured. The driver of the IGBT described above is not for the IGBT illustrated in FIG. 10A but refers to a driver of an IGBT (not illustrated) connected in parallel with the semiconductor device 2A.

V_{g} and V_{Q} illustrated in FIG. 10B are the voltages illustrated in FIG. 10A, and i_{L}, i_{Q}, and I_{D} are the currents illustrated in FIG. 10A. Note that V_{DG} is a voltage of the electrode 50 of the semiconductor device 2A. The voltage of the electrode 50 uses the anode electrode 11 as a standard.

As illustrated in the lowermost time chart, in the second embodiment, immediately before the IGBT is turned ON, that is, immediately before the semiconductor device 2A is turned OFF, a potential for forming the channel region 21ch is supplied to the electrode 50. By this, the semiconductor device 2A can be switched at a high speed. Moreover, after the recovery operation of the semiconductor device 2A is finished, the electrode 50 is turned OFF. Here, a timing of turning OFF the electrode 50 may be any timing in a period when the semiconductor device 2A is turned OFF and is sufficient if at a time when or before the semiconductor device 2A is turned ON. A width of the timing exists because, as described above, the electric field can be applied in the OFF state and the breakdown voltage can be had even in the switching state or the static OFF state due to the embodiment having the semiconductor region 31 that is the p-type high-concentration layer; this is disclosed for the first time in the embodiment. By this, a diode whose ON voltage is low and with little switching loss can be formed. Here, one characteristic of the embodiment is that if the timing of turning OFF the electrode 50 is made to be immediately after the recovery operation of the semiconductor device 2A is finished, the diode with the low ON voltage can be realized because a high-speed recovery operation is realized and the channel region 21ch disappears during conduction.

### Variation of the Second Embodiment

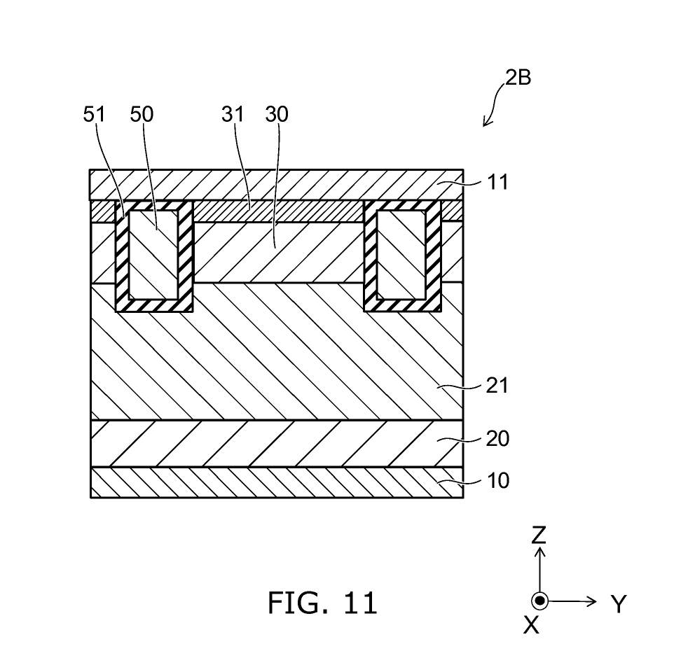

FIG. 11 is a schematic cross-sectional view illustrating a semiconductor device according to a variation of the second embodiment.

In a semiconductor device 2B illustrated in FIG. 11, the semiconductor region 31 extends continuously in the Y-direction and contacts the adjacent insulating film 51. Other structures are similar to those in FIG. 9A. Moreover, basic operations thereof are also similar thereto. Note that there is an advantage where the ON voltage can be reduced because the width of the semiconductor region 31 is wider than that in the second embodiment. In the semiconductor device 2B as well, both speeding up the recovery speed and increasing the breakdown tolerance upon recovery, that is, enlarging the safe operation area (SOA), can be achieved.

### Third Embodiment

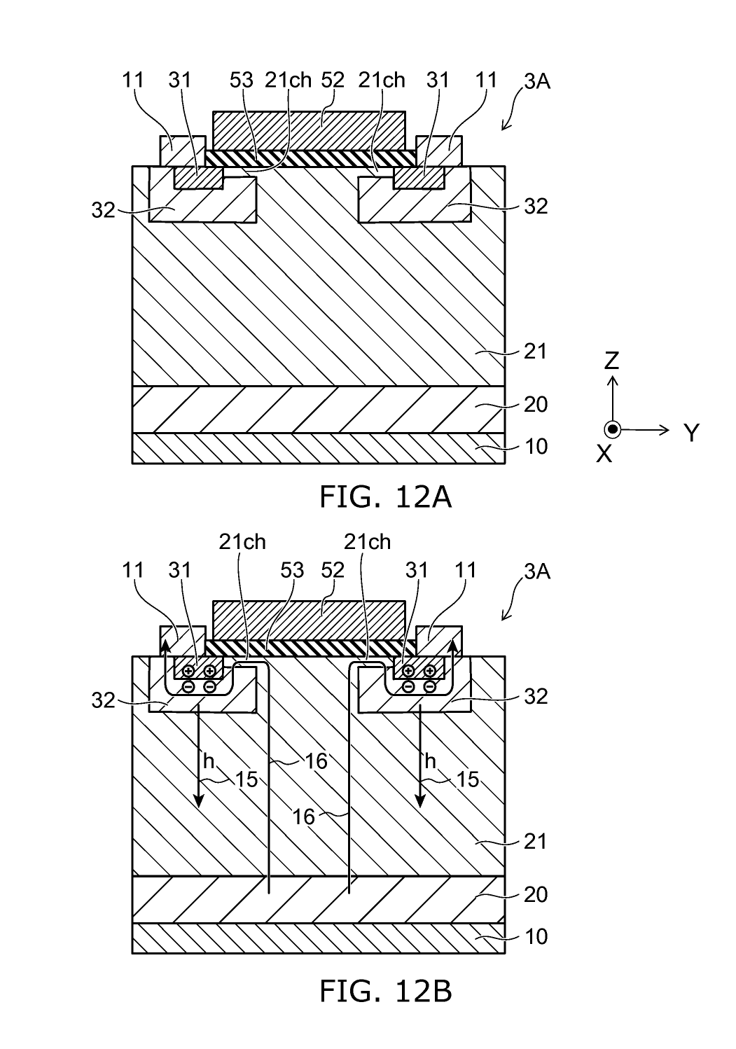

FIG. 12A is a schematic cross-sectional view illustrating a semiconductor device according to a third embodiment, and FIG. 12B is a schematic cross-sectional view illustrating an operation thereof.

A semiconductor device 3A disposes the electrode 50 described above in a planar form. Moreover, components of the semiconductor device described above can be compounded in the semiconductor device 3A. The semiconductor device 3A illustrated in FIG. 12A is provided with the cathode electrode 10, the anode electrode 11, an insulating region 53, the semiconductor region 20, and the semiconductor region 21. The semiconductor region 21 is provided between the semiconductor region 20 and the anode electrode 11 and between the semiconductor region 20 and the insulating region 53. The insulating region 53 is lined up on the anode electrode 11. The anode electrode 11 is provided on the semiconductor region 31 and on the semiconductor region 32. The semiconductor region 32 (second semiconductor region) is of the same conductivity type as the semiconductor region 30 described above and has a similar impurity concentration thereto.

The semiconductor region 32 is provided between the semiconductor region 21 and the anode electrode 11 and between the semiconductor region 21 and the insulating region 53. A portion of the semiconductor region 32 contacts the anode electrode 11. The semiconductor portion 21 is sandwiched between a portion of the semiconductor region 32 other than this portion and the insulating region 53. In the semiconductor device 3A, a portion of this sandwiched semiconductor region 21 is configured to be the channel region 21ch.

The semiconductor region 31 is provided between the semiconductor region 32 and the anode electrode 11 and between the semiconductor region 32 and the insulating region 53. A portion of the semiconductor region 31 contacts the semiconductor region 21. A portion of the semiconductor region 31 other than this portion contacts the anode electrode 11. Moreover, the semiconductor device 3A is provided with an electrode 52 so that the insulating region 53 is sandwiched between the electrode 52 and the semiconductor region 21. Note that the electrode 52 may be connected to the anode electrode 11.

An operation of the semiconductor device 3A is illustrated in FIG. 12B.

In the ON state, the voltage of the forward bias is applied between the cathode and the anode. Most of the electrons (e) arrive directly below the semiconductor region 32 from the semiconductor region 20 via the semiconductor region 21. The channel region 21ch is the n-type. Therefore, the electrons flow to the anode electrode 11 via the channel region 21ch, which has the low potential, rather than crossing over the energy barrier between the semiconductor region 21 and the semiconductor region 32.

Note that the semiconductor region 32 is in resistive contact or in Schottky contact with the anode electrode 11. Because of this, the junction between the semiconductor region 32 and the anode electrode 11 is not an energy barrier for the electrons (e). By this, the electrons are discharged to the anode electrode 11 via the semiconductor region 32.

That is, the electrons (e) flow into the anode electrode 11 via the semiconductor region 20, the semiconductor region 21, the channel region 21ch, and the semiconductor region 32. By this, the electron current 16 is formed between the cathode and the anode.

In this manner, the junction between the semiconductor region 32 and the anode electrode 11 is not an energy barrier for the electrons (e). However, the junction between the semiconductor region 31, which is the p-type high-concentration layer, and the n-type semiconductor region 21 is an energy barrier for the electrons (e). Therefore, the electrons (e) that arrive in front of the semiconductor region 31 are less likely to flow into the semiconductor region 31. After this, the electrons (e) move in the horizontal direction below the semiconductor region 31, that is, the direction approximately parallel to the Y-direction.

By this horizontal movement of the electrons (e), the voltage drop occurs below the semiconductor region 31. By this, the semiconductor region 31 contacting the anode electrode 11 becomes the positive electrode, and the semiconductor region 21 and the semiconductor region 32 positioned below the semiconductor region 31 are biased to become negative electrodes relative to the semiconductor region 31.

By this bias, the energy barrier against the holes between the semiconductor region 21 and the semiconductor region 32 and between the semiconductor region 21 and the semiconductor region 31 is lowered below the semiconductor region 31. By this, the holes (h) are injected in the semiconductor region 21 and the semiconductor region 32 from the semiconductor region 31. The hole current 15 is formed by these injected holes (h).

The hole current 15 increases as the width of the semiconductor region 31 in the Y-direction or in the X-direction, or the contact surface area between the semiconductor region 31 and the anode electrode 11, increases. In other words, the injection amount of the holes from the anode side is adjusted by this width or this contact surface area.

Furthermore, in the semiconductor device 3A, the electrons are less likely to flow to the anode electrode 11 from the semiconductor region 21 directly below the semiconductor region 32 via the semiconductor region 32. Therefore, hole injection from the semiconductor region 32 is reliably suppressed. Moreover, during reverse bias application, in the channel region 21ch, the depletion layer spreads with the junction of the semiconductor region 32 and the semiconductor region 21 and the junction of the semiconductor region 31 and the semiconductor region 21 as the starting points. Because of this, the channel region 21ch is completely depleted. Therefore, in the semiconductor device 3A, the reverse current is reliably suppressed when the reverse bias is applied. Moreover, when a negative potential relative to the anode electrode 11 is applied on the electrode 52, the depletion layer in the channel region 21ch spreads even more easily.

In this manner, according to the semiconductor device 3A, both speeding up the recovery speed and increasing the breakdown tolerance upon recovery, that is, enlarging the safe operation area (SOA), can be achieved. Note that the semiconductor device 3A turns the channel region 21ch in the first embodiment and the second embodiment in a horizontal direction and that the variations described above can similarly be applied and exhibit similar effects.

### Fourth Embodiment

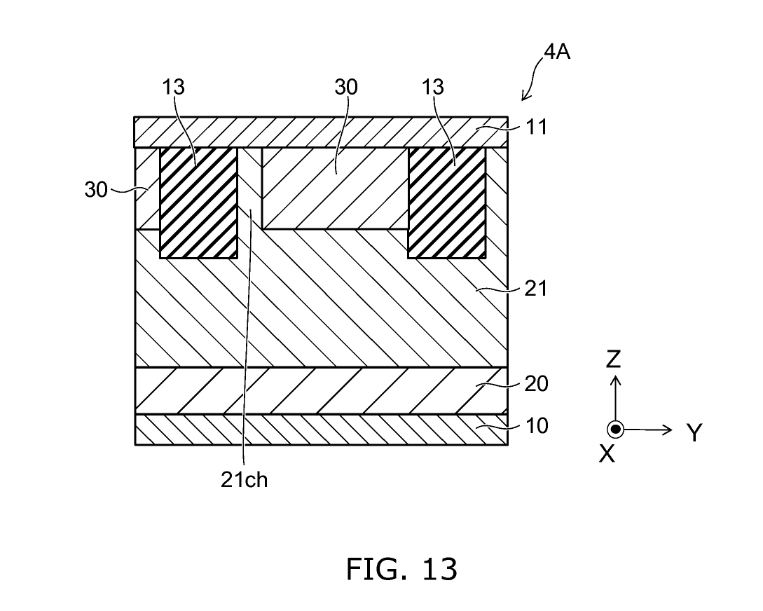

FIG. 13 is a schematic cross-sectional view illustrating a semiconductor device according to a fourth embodiment.

A semiconductor device 4A illustrated in FIG. 13 has a structure where the semiconductor region 31 is removed from a structure of the semiconductor device 1A described above.

In the semiconductor device 4A, because the semiconductor region 31 is removed, during forward bias application, hole injection from the anode side is further suppressed. Moreover, because the width of the channel region 21 in the Y-direction is narrow, at 1 μm or less, during reverse bias application, the channel region 21ch is completely depleted with the junction of the semiconductor region 30 and the semiconductor region 21 as the starting point. Therefore, in the semiconductor device 4A, the reverse current is reliably suppressed when the reverse bias is applied. Therefore, in the semiconductor device 4A as well, both speeding up the recovery speed and increasing the breakdown tolerance upon recovery, that is, enlarging the safe operation region, can be achieved.

In the above embodiments, in expressions such as “component A is provided on component B,” “on” is sometimes used in the sense that the component A is provided above the component B without the component A contacting the component B, in addition to the sense that the component A is provided on the component B with the component A contacting the component B. Moreover, “component A is provided above component B” is sometimes applied in situations where the component A and the component B are inverted so that the component A is positioned below the component B, and where the component A and the component B are lined up horizontally. This is because a structure of the semiconductor devices does not change before or after rotation when the semiconductor devices according to the embodiments are rotated.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode;
a first semiconductor region of a first conductivity type provided between the first electrode and the second electrode, the first semiconductor region contacting the first electrode;
a second semiconductor region of a second conductivity type provided between the first semiconductor region and the second electrode;
an insulating region extending from the second electrode to a side of the first semiconductor region; and
a third semiconductor region of the first conductivity type provided in at least a portion of a region between the second semiconductor region and the insulating region, the third semiconductor region contacting the first semiconductor region.

2. The device according to claim 1, wherein the third semiconductor region is a portion of the first semiconductor region.

3. The device according to claim 1, further comprising: a fourth semiconductor region of the second conductivity type provided between the second electrode and the first semiconductor region and between the second electrode and the second semiconductor region, the fourth semiconductor region contacting the second electrode and the insulating region.

4. The device according to claim 3, wherein an impurity concentration of the fourth semiconductor region is greater than an impurity concentration of the second semiconductor region.

5. The device according to claim 1, wherein a distance between the insulating region and the first electrode is shorter than a distance between the second semiconductor region and the first electrode.

6. The device according to claim 3, wherein the fourth semiconductor region is divided into a plurality of regions in a second direction intersecting a first direction from the first electrode toward the second electrode, and each of the regions is lined up in the second direction.

7. The device according to claim 1, further comprising:
one other insulating region extending from the second electrode to the side of the first semiconductor region; and
one other third semiconductor region in at least a portion of a region between the second semiconductor region and the one other insulating region.

8. The device according to claim 7, wherein the one other third semiconductor region is a portion of the first semiconductor region.

9. The device according to claim 8, further comprising: one other fourth semiconductor region provided between the second electrode and the first semiconductor region and between the second electrode and the one other second semiconductor region, the fourth semiconductor region contacting the second electrode and the separate insulating region.

10. The device according to claim 1, further comprising: a connecting region contacting the second electrode, and the connecting region being provided between the second electrode and the insulating region.

11. The device according to claim 1, further comprising:
a third electrode electrically insulated from the second electrode, and the third electrode being provided in the insulating region,
the third semiconductor region being formed by applying a positive bias relative to the first electrode on the third electrode.

12. The device according to claim 11, further comprising: a fourth semiconductor region of the second conductivity type provided between the second electrode and the first semiconductor region and between the second electrode and the second semiconductor region, the fourth semiconductor region contacting the second electrode and the insulating region.

13. The device according to claim 12, further comprising:
one other insulating region extending from the second electrode to the side of the first semiconductor region; and
one other third electrode electrically insulated from the second electrode and provided in the separate insulating region,
the fourth semiconductor region contacts the insulating region and the one other insulating region.

14. A semiconductor device, comprising:
a first electrode;
a second electrode;
a first semiconductor region of a first conductivity type provided between the first electrode and the second electrode, the first semiconductor region contacting the first electrode;
a second semiconductor region of a second conductivity type provided between the first semiconductor region and the second electrode;
an insulating region lined up on the second electrode, and the insulating region contacting the first semiconductor region; and
a third semiconductor region of the first conductivity type provided in at least a portion of a region between the second semiconductor region and the insulating region, the third semiconductor region contacting the first semiconductor region.

15. The device according to claim 14, wherein the third semiconductor region is a portion of the first semiconductor region.

16. The device according to claim 14, further comprising: a fourth semiconductor region of the second conductivity type provided between the second electrode and the second semiconductor region, the fourth semiconductor region contacting the second electrode and the insulating region.

17. The device according to claim 16, wherein an impurity concentration of the fourth semiconductor region is greater than an impurity concentration of the second semiconductor region.

18. The device according to claim 16, wherein the fourth semiconductor region is divided into a plurality of regions in a second direction intersecting a first direction from the first electrode toward the second electrode, and each of the regions is lined up in the second direction.

19. The device according to claim 14, further comprising:
a third electrode electrically insulated from the second electrode, and the third electrode sandwiching the insulating region between the third electrode and the second semiconductor region,
the third semiconductor region being formed by applying a positive bias relative to the first electrode on the third electrode.

20. The device according to claim 14, further comprising:
one other second electrode lined up on the second electrode;
one other second semiconductor region provided between the first semiconductor region and the separate second electrode; and
one other third semiconductor region provided in at least a portion of a region between the one other second semiconductor region and the insulating region, the one other third semiconductor region contacting the first semiconductor region.
